(19) United States
(12) Patent Application Publication
(10) Pub. No.: US 2026/0059948 A1
(43) Pub. Date: Feb. 26, 2026

(54) DISPLAY PANEL, PREPARATION METHOD FOR DISPLAY PANEL, AND DISPLAY APPARATUS

(71) Applicants: Hefei Visionox Technology Co., Ltd., Hefei (CN); Hefei Visionox Electronics Co., Ltd., Hefei (CN); Visionox Technology Inc., Kunshan (CN)

(72) Inventors: Yuting FU, Hefei (CN); Chung-chun LEE, Kunshan (CN); Cheng-yi LIN, Hefei (CN); Weiju HUANG, Hefei (CN); Peng QIN, Kunshan (CN); Zhiwei FAN, Hefei (CN); Ying-ao CHEN, Hefei (CN); Zihao GUO, Hefei (CN)

(73) Assignees: Hefei Visionox Technology Co., Ltd., Hefei (CN); Hefei Visionox Electronics Co., Ltd., Hefei (CN); Visionox Technology Inc., Kunshan (CN)

(21) Appl. No.: 19/306,989

(22) Filed: Aug. 21, 2025

(30) Foreign Application Priority Data
Aug. 23, 2024 (CN) 202411173575.3

(51) Int. Cl. H10K 59/122; H10K 59/12; H10K 59/80

(52) U.S. Cl. CPC H10K 59/122; H10K 59/80521; H10K 59/873; H10K 59/1201

(57) ABSTRACT

The present application discloses a display panel, a preparation method for a display panel, and a display apparatus. The display panel includes a substrate, an isolation structure, a light-emitting unit, and a first encapsulation layer. The isolation structure is disposed on a side of the substrate and encloses an isolation opening. The isolation structure includes a first isolation portion and a second isolation portion. An orthographic projection of the first isolation portion on the substrate is within an orthographic projection of the second isolation portion on the substrate. The first isolation portion includes a first sub-portion and protrusions or recesses disposed on a sidewall of the first sub-portion facing the isolation opening. At least part of the light-emitting unit is disposed in the isolation opening. The first encapsulation layer includes an encapsulation portion. The encapsulation portion covers at least part of the protrusions or recesses.

### CROSS-REFERENCE TO RELATED APPLICATIONS

The present application claims priority to the Chinese Patent Application No. 202411173575.3, filed on Aug. 23, 2024, and the entire contents of the aforementioned application are hereby incorporated by reference in its entirety.

### FIELD

The present application relates to the field of display technologies, and in particular to a display panel, a preparation method for a display panel, and a display apparatus.

### BACKGROUND

Organic light-emitting diodes (OLEDs) as well as flat panel display apparatuses based on technologies such as light-emitting diodes (LEDs) have been widely applied in various consumer electronics such as mobile phones, televisions, laptop computers, and desktop computers due to their advantages such as high image quality, energy efficiency, slim design, and wide applications, making them mainstream in display apparatuses.

However, the usage performance of conventional OLED display products needs to be improved.

### SUMMARY

The present application provides a display panel, a preparation method for a display panel, and a display apparatus, to improve a performance of the display panel.

In one embodiment, the present application provides a display panel. The display panel includes a substrate, an isolation structure, and a light-emitting unit. The isolation structure is disposed on a side of the substrate and encloses an isolation opening. The isolation structure includes a first isolation portion and a second isolation portion stacked in a direction away from the substrate. An orthographic projection of the first isolation portion on the substrate is within an orthographic projection of the second isolation portion on the substrate. The first isolation portion includes a first sub-portion and a plurality of protrusions or recesses disposed on a sidewall of the first sub-portion facing the isolation opening; at least part of the light-emitting unit is disposed in the isolation opening; the first encapsulation layer includes an encapsulation portion, and the encapsulation portion is disposed on a side of the light-emitting unit facing away from the substrate; and the encapsulation portion covers at least part of the protrusions or recesses.

In some embodiments, the isolation structure further includes a third isolation portion disposed on a side of the first isolation portion close to the substrate, and an orthographic projection of the protrusions or recesses on the substrate is within an orthographic projection of the third isolation portion on the substrate; the light-emitting unit includes a first electrode lapping the third isolation portion; the encapsulation portion covers the first electrode;
in one embodiment, the first electrode is in contact with part of the protrusions or recesses;
in one embodiment, the third isolation portion includes a second sub-portion, and an extension sub-portion disposed on a side of the second sub-portion facing the isolation opening, where the second sub-portion is in contact with a surface of a side of the first sub-portion facing the substrate, the extension sub-portion extends, relative to the surface of the side of the first sub-portion facing the substrate, toward the isolation opening in a direction parallel to the substrate, and a ratio Z of an extension length of the extension sub-portion in the direction parallel to the substrate to a height of the protrusions satisfies: 1.5≤Z≤3;
in one embodiment, the extension length L1 of the extension sub-portion satisfies: 0.1 μm≤L1≤0.15 μm;
in one embodiment, the height H1 of the protrusions satisfies: 0.05 μm≤H1≤0.07 μm; and
in one embodiment, an orthographic projection of the third isolation portion on the substrate is within an orthographic projection of the second isolation portion on the substrate.
In some embodiments, the encapsulation portion extends to a side of the isolation structure facing away from the substrate;
in one embodiment, a material of the first encapsulation layer includes an inorganic material;
in one embodiment, the plurality of protrusions are burr-like;
in one embodiment, an orthographic projection of the protrusions on the first sub-portion in a direction parallel to the substrate is bar-shaped;
in one embodiment, an orthographic projection of the protrusions on the first sub-portion in a direction parallel to the substrate is bar-shaped, and the protrusions extend in the direction parallel to the substrate; and
in one embodiment, an orthographic projection of the protrusions on the first sub-portion in a direction parallel to the substrate is bar-shaped, and the protrusions extend along a curved trajectory.

In some embodiments, materials of both the third isolation portion and the first sub-portion include a conductive material;
in one embodiment, an oxidation rate of the first sub-portion is greater than an oxidation rate of the third isolation portion;
in one embodiment, a material of the third isolation portion includes at least one of molybdenum, titanium, or copper; and
in one embodiment, a material of the first sub-portion includes aluminum.

In some embodiments, a material of the protrusions includes an oxide;
in one embodiment, the material of the protrusions and the material of the first sub-portion include a same element;
in one embodiment, the material of the first sub-portion includes a metal, and the material of the protrusions includes an oxide of the metal; and
in one embodiment, the material of the first sub-portion includes aluminum, and the material of the protrusions includes aluminum oxide.

In some embodiments, the first isolation portion includes a first surface facing the substrate and a second surface facing away from the substrate, where an orthographic projection of the second surface on the substrate is within an orthographic projection of the first surface on the substrate; and
in one embodiment, in a direction perpendicular to the substrate, a cross-sectional shape of the first sub-portion of the first isolation portion is a regular trapezoid.

In some embodiments, the first isolation portion includes a first surface facing the substrate and a second surface facing away from the substrate, where an orthographic projection of the first surface on the substrate is within an orthographic projection of the second surface on the substrate; and
in one embodiment, in a direction perpendicular to the substrate, a cross-sectional shape of the first sub-portion of the first isolation portion is an inverted trapezoid.

In some embodiments, the third isolation portion includes a third surface facing the substrate, a fourth surface facing away from the substrate, and a side surface connecting the third surface and the fourth surface, the light-emitting unit includes a first electrode, where the first electrode extends to the fourth surface via the side surface; and
in one embodiment, the first electrode extends from the fourth surface to a sidewall of the first isolation portion facing the isolation opening, and covers at least part of the protrusions or recesses.

In some embodiments, the display panel further includes a pixel define layer, where the pixel define layer includes a pixel defining portion and a pixel opening enclosed by the pixel defining portion, the pixel opening is in communication with the isolation opening, part of the light-emitting unit is located in the pixel opening, and the isolation structure is disposed on a side of the pixel defining portion facing away from the substrate.

In some embodiments, the display panel further includes a pixel define layer, where the pixel define layer includes a pixel defining portion, and a pixel opening and a relief opening that are enclosed by the pixel defining portion, the isolation structure is disposed in the relief opening, and the first electrode extends from the pixel opening toward the relief opening, and laps the third isolation portion of the isolation structure.

In one embodiment, the present application provides a display panel. The display panel includes: a substrate; an isolation structure disposed on a side of the substrate and enclosing an isolation opening, where the isolation structure includes a first isolation portion and a second isolation portion stacked in a direction away from the substrate, an orthographic projection of the first isolation portion on the substrate is within an orthographic projection of the second isolation portion on the substrate, and the first isolation portion includes a first sub-portion and an oxide layer disposed on a sidewall of the first sub-portion facing the isolation opening; and at least part of a light-emitting unit is disposed in the isolation opening.

In some embodiments, the display panel further includes a first encapsulation layer, and the first encapsulation layer includes an encapsulation portion, where the encapsulation portion is disposed on a side of the light-emitting unit facing away from the substrate and covers at least part of the oxide layer;
in one embodiment, the encapsulation portion extends to a side of the isolation structure facing away from the substrate;
in one embodiment, a surface roughness of the oxide layer is greater than a surface roughness of a side of the first sub-portion facing away from the substrate;
in one embodiment, the oxide layer includes a plurality of protrusions disposed on a side of the first sub-portion facing the isolation opening;
in one embodiment, the protrusions are burr-like; and
in one embodiment, a material of the first encapsulation layer includes an inorganic material.

In some embodiments, the isolation structure further includes a third isolation portion disposed on a side of the first isolation portion close to the substrate; an orthographic projection of the oxide layer on the substrate is within an orthographic projection of the third isolation portion on the substrate; the light-emitting unit includes a first electrode lapping the third isolation portion;
in one embodiment, the first electrode is in contact with at least part of the oxide layer;
in one embodiment, the third isolation portion includes a second sub-portion, and an extension sub-portion disposed on a side of the second sub-portion facing the isolation opening, where the second sub-portion is in contact with a surface of a side of the first sub-portion facing the substrate, the extension sub-portion protrudes, relative to the surface of the side of the first sub-portion facing the substrate, toward the isolation opening in a direction parallel to the substrate, and a ratio Z of an extension length of the extension sub-portion in the direction parallel to the substrate to a thickness of the oxide layer satisfies: 1.5≤Z≤3;
in one embodiment, the extension length L1 of the extension sub-portion satisfies: 0.05 μm<L1≤0.15 μm;
in one embodiment, the extension length L1 of the extension sub-portion satisfies: 0.1 μm≤L1≤0.15 μm; and
in one embodiment, the thickness H2 of the oxide layer satisfies: 0.05 μm≤H2≤0.07 μm.

In some embodiments, the light-emitting unit further includes a second electrode and a light-emitting functional layer, where the second electrode, the light-emitting functional layer, and the first electrode are stacked in a direction away from the substrate; and
in one embodiment, the light-emitting functional layer covers part of the extension sub-portion;
in one embodiment, the extension sub-portion includes a first part, and a second part, where the first part is covered by the light-emitting functional layer, the second part is exposed relative to the light-emitting functional layer, and a length L2 of the second part in a direction parallel to the substrate satisfies: 0.02 μm<L2<0.15 μm.

In one embodiment, the present application provides a preparation method for a display panel. The method includes: forming an isolation structure on a side of a substrate, and enclosing an isolation opening by the isolation structure, where the isolation structure includes a first isolation portion and a second isolation portion stacked in a direction away from the substrate, an orthographic projection of the first isolation portion on the substrate is within an orthographic projection of the second isolation portion on the substrate, and the first isolation portion includes a first sub-portion and an oxide layer formed on a sidewall of the first sub-portion facing the isolation opening; and forming a light-emitting unit in the isolation opening.

In some embodiments, the step of forming the isolation structure on the side of the substrate includes: forming a first isolation material layer on the side of the substrate; forming a second isolation material layer on a side of the first isolation material layer facing away from the substrate; performing a patterning treatment on the first isolation material layer and the second isolation material layer to form the second isolation portion and the first sub-portion; forming the oxide layer on a sidewall of the first sub-portion facing the isolation opening through an in-situ growth process;
in one embodiment, the preparation method further includes: forming a first encapsulation layer, where the first encapsulation layer includes an encapsulation portion, and the encapsulation portion is disposed on a side of the light-emitting unit facing away from the substrate; and the encapsulation portion covering at least part of the oxide layer.

In one embodiment, the present application provides a display apparatus. The display apparatus includes the display panel according to any one of the preceding embodiments, or the display panel prepared by the preparation method according to any one of the preceding embodiments.

Embodiments of the present application provide a display panel, a preparation method for a display panel, and a display apparatus. The display panel includes a substrate, an isolation structure, a light-emitting unit, and a first encapsulation layer. The isolation structure is disposed on a side of the substrate and encloses an isolation opening. The isolation structure includes a first isolation portion and a second isolation portion stacked in a direction away from the substrate. An orthographic projection of the first isolation portion on the substrate is within an orthographic projection of the second isolation portion on the substrate. Therefore, the isolation structure can separate a light-emitting material to form light-emitting units and each light-emitting unit is located in each corresponding isolation opening, without the need for a mask, to lower costs. The first isolation portion includes a first sub-portion and protrusions or recesses disposed on a sidewall of the first sub-portion facing the isolation opening, the first encapsulation layer includes an encapsulation portion, and the encapsulation portion is disposed on a side of the light-emitting unit facing away from the substrate; and the encapsulation portion covers at least part of the protrusions or recesses, to increase a contact area between the encapsulation portion and the isolation structure, to lower a risk of delamination between the encapsulation portion and the isolation structure, and to improve an encapsulation performance of the encapsulation portion on the light-emitting unit.

### BRIEF DESCRIPTION OF THE DRAWINGS

In order to describe the embodiments of the present application, the drawings for illustration of the embodiments of the present application will be briefly introduced below. The drawings as described below are only for some of the embodiments of the present application, and other drawings can also be obtained from these drawings.

FIG. 1 is a schematic sectional view of a display panel according to some embodiments of the present application;

FIG. 2 is a schematic sectional view of a display panel in a direction parallel to a substrate according to some embodiments of the present application;

FIG. 3 is a partial schematic sectional view of a display panel according to some embodiments of the present application;

FIG. 4 is a further schematic sectional view of a display panel according to some embodiments of the present application;

FIG. 5 is a schematic sectional view of a display panel according to some other embodiments of the present application;

FIG. 6 is a further partial schematic sectional view of a display panel according to some embodiments of the present application;

FIG. 7 is a schematic sectional view of a display panel according to still other embodiments of the present application;

FIG. 8 is a flowchart of a preparation method for a display panel according to some embodiments of the present application; and

FIG. 9 is a further flowchart of a preparation method for a display panel according to some embodiments of the present application.

Reference numerals in the drawings are as follows:
display panel 100; substrate 10; isolation structure 20; isolation opening 21; third isolation portion 22; second sub-portion 221; extension sub-portion 222; third surface 223; fourth surface 224; side surface 225; first isolation portion 23; first sub-portion 231; protrusion 232; first surface 233; second surface 234; recess 235; second isolation portion 24; light-emitting unit 30; first electrode 31; light-emitting functional layer 32; second electrode 33; encapsulation portion 40; pixel define layer 50; pixel defining portion 51; pixel opening 52.

### DETAILED DESCRIPTION OF THE EMBODIMENTS

The embodiments of the present application are further described in detail below with reference to the accompanying drawings and embodiments. The following detailed description of the embodiments and the accompanying drawings are used to illustrate the principle of the present application in an exemplary manner, but shall not be used to limit the present application. That is, the present application is not limited to the described embodiments.

In the description of the present application, it should be noted that “a plurality of” means two or more, unless otherwise specified. The orientation or position relationship indicated by the terms “upper”, “lower”, “left”, “right”, “inner”, “outer”, etc. is merely for the convenience of describing the present application and simplifying the description, rather than indicating or implying that a device or element referred to must have a particular orientation or be constructed and operated in a particular orientation, and therefore should not be construed as limiting the present application. In addition, the terms “first”, “second” and “third” are for descriptive purposes only and should not be construed as indicating or implying relative importance. The term “perpendicular” does not mean being perpendicular in the strict sense, but within an allowable range of tolerance. The term “parallel” does not mean being parallel in the strict sense, but within an allowable range of tolerance.

The phrase “embodiment” mentioned in the present application means that the specific features, structures and characteristics described with reference to the embodiment may be encompassed in at least one embodiment of the present application. This phrase in various places in the specification does not necessarily refer to the same embodiment or an independent or alternative embodiment exclusive of other embodiments. It is understood explicitly and implicitly that the embodiments described in the present application may be combined with other embodiments.

The orientation terms in the following description all indicate directions shown in the accompanying drawings, and do not limit the specific structure in the present application. In the description of the present application, it should be noted that, the terms “mount”, “connected”, or “connect” should be interpreted in a broad sense unless explicitly defined and limited otherwise. In one embodiment, they may be a fixed connection, a detachable connection, or an integral connection; or may mean a direct connection, or an indirect connection by means of an intermediate medium. The specific meanings of the terms mentioned above in the present application may be construed according to specific circumstances.

Embodiments of the present application provide a display panel. The display panel may be an organic light-emitting diode (OLED) display panel, or another type of display panel, such as a micro light-emitting diode (Micro-LED) display panel or a quantum dot light-emitting diode (QLED) display panel.

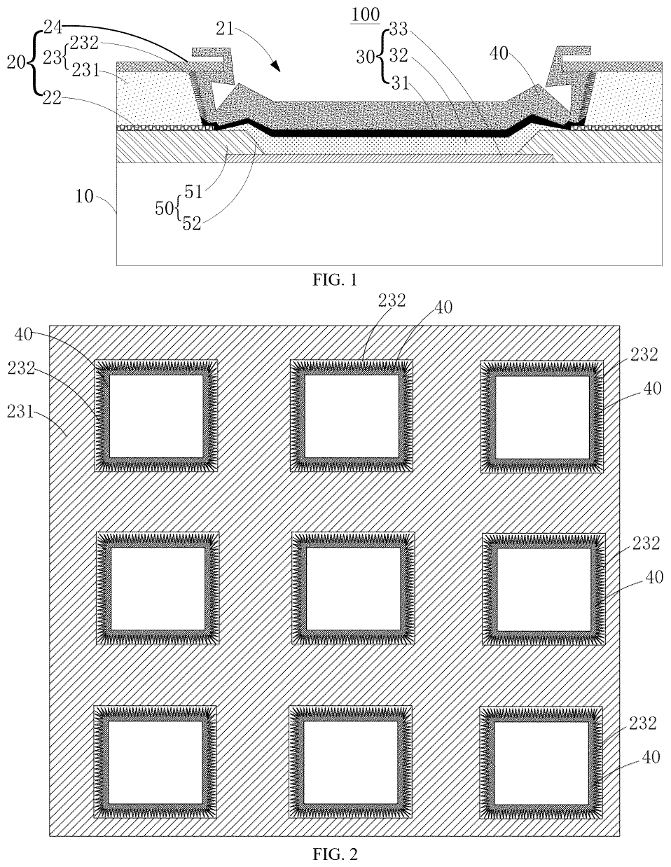

Referring to FIGS. 1 to 3, in a first embodiment, the present application provides a display panel 100. The display panel includes a substrate 10, an isolation structure 20, and a light-emitting unit 30. The isolation structure 20 is disposed on a side of the substrate 10 and encloses an isolation opening 21. The isolation structure 20 includes a first isolation portion 23 and a second isolation portion 24 stacked in a direction away from the substrate 10. An orthographic projection of the first isolation portion 23 on the substrate 10 is within an orthographic projection of the second isolation portion 24 on the substrate 10. The first isolation portion 23 includes a first sub-portion 231 and protrusions 232 or recesses 235 disposed on a sidewall of the first sub-portion 231 facing the isolation opening 21; at least part of the light-emitting unit 30 is disposed in the isolation opening 21; the first encapsulation layer includes an encapsulation portion 40, and the encapsulation portion 40 is disposed on a side of the light-emitting unit 30 facing away from the substrate 10; and the encapsulation portion 40 covers at least part of the protrusions 232 or recesses 235.

The substrate 10 includes a substrate and a drive circuit layer disposed on the substrate. The substrate may be a rigid substrate made of glass, plastic, or another material, or a flexible substrate made of polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), cellulose acetate propionate (CAP), or another material. A drive circuit for controlling a light-emitting unit 30 to emit light is disposed in the drive circuit layer. The drive circuit layer is generally composed of inorganic film layers such as a metal layer, a semiconductor layer (active layer), and an insulation layer. The drive circuit for controlling the light-emitting unit 30 to emit light may be formed by patterning these inorganic film layers, and there may be various embodiments of the specific circuit structure of the drive circuit, which will not be described in detail herein.

The isolation structure 20 encloses the isolation opening 21, and the isolation structure 20 includes the first isolation portion 23 and the second isolation portion 24 stacked in the direction away from the substrate 10. The orthographic projection of the first isolation portion 23 on the substrate 10 is within the orthographic projection of the second isolation portion 24 on the substrate 10. When a light-emitting material is deposited on a side of the isolation structure 20 facing away from the substrate 10, the light-emitting material can be separated by the isolation structure 20 to form light-emitting units 30 that are separate from each other, thereby eliminating the need for a fine metal mask to prepare the light-emitting units 30, reducing the development and use of the fine metal mask, and lowering preparation costs. In one embodiment, there may be a plurality of isolation openings 21, and the plurality of light-emitting units 30 are disposed in the plurality of isolation openings 21 in a one-to-one correspondence, thereby reducing carrier crosstalk between the light-emitting units 30, and improving the display performance of the display panel 100.

The display panel 100 may further include the first encapsulation layer, and the first encapsulation layer includes the encapsulation portion 40 covering the plurality of light-emitting units 30. The encapsulation portion 40 can act as an independent encapsulation for each light-emitting unit 30, to lower a risk of the light-emitting unit 30 being affected by factors including moisture, and improving reliability of the display panel 100. It should be noted that there may be a plurality of encapsulation portions 40, and the plurality of encapsulation portions 40 may encapsulate the plurality of light-emitting units 30 in a one-to-one correspondence, thereby improving encapsulation reliability for the light-emitting units 30.

It is understandable that the encapsulation portion 40 is disposed on a side of the light-emitting units 30 facing away from the substrate 10, and extends toward a sidewall of the isolation structure 20 facing the isolation opening 21, to prolong an intrusion path of moisture and oxygen, thereby improving the encapsulation performance. However, due to a limited bonding capability between the current encapsulation portion 40 and isolation structure 20, the encapsulation portion 40 is prone to peeling from the isolation structure 20 during the subsequent process or usage, which affects the encapsulation performance. In addition, the encapsulation portion 40 during the peeling may further cause the light-emitting unit 30 to peel off, thereby affecting the display performance of the display panel 100.

In view of this, in the display panel 100 of the embodiments of the present application, the first isolation portion 23 is configured to include the first sub-portion 231 and the protrusions 232 or recesses 235 located on the sidewall of the first sub-portion 231 facing the isolation opening 21, and the encapsulation portion 40 covers at least part of the protrusions 232 or recesses 235, to increase a contact area between the encapsulation portion 40 and the isolation structure 20, enhancing a bonding capability between the encapsulation portion 40 and the isolation structure 20, and lowering a risk of peeling of the encapsulation portion 40 from the isolation structure 20 during the subsequent process or usage.

It should be noted that when the recess 235 is formed on the sidewall of the first sub-portion 231 facing the isolation opening 21, protruding portions are disposed around the recess 235 and protrude relative to the recess 235, the recess 235 is enclosed by the protruding portions, and the recess 235 is formed between two adjacent protruding portions. An orthographic projection of the protrusions 232 or recesses 235 on the substrate 10 is within an orthographic projection of a third isolation portion 22 on the substrate 10. That is, in the direction parallel to the substrate 10, a distance from a side of the third isolation portion 22 facing the isolation opening 21 to a side of the first sub-portion 231 facing the isolation opening 21 is greater than or equal to a distance from an end of the protrusion 232 close to the isolation opening 21 to the first sub-portion 231, or the distance from the side of the third isolation portion 22 facing the isolation opening 21 to the side of the first sub-portion 231 facing the isolation opening 21 is greater than or equal to a depth of the recess 235, and a sidewall of the third isolation portion 22 facing the isolation opening 21 is flush with the end of the protrusion 232 close to the isolation opening 21 or protrudes relative to the end of the protrusion 232 close to the isolation opening 21, to avoid the protrusions 232 from blocking the sidewall of the third isolation portion 22 facing the isolation opening 21.

Referring to FIG. 1, in some embodiments, the isolation structure 20 further includes the third isolation portion 22 disposed on a side of the first isolation portion 23 close to the substrate, and the orthographic projection of the protrusions 232 or recesses 235 on the substrate 10 is within the orthographic projection of the third isolation portion 22 on the substrate 10; each light-emitting unit 30 includes a first electrode 31 lapping the third isolation portion 22; and the encapsulation portion 40 covers the first electrode 31.

The third isolation portion 22 is disposed on the side of the first isolation portion 23 close to the substrate 10, and the disposal of the third isolation portion 22 is equivalent to enabling the isolation opening 21 to have a large height drop, to facilitate separating the light-emitting material to form the light-emitting units 30. Each light-emitting unit 30 may include the first electrode 31, a light-emitting functional layer 32, and a second electrode 33 that are stacked. The first electrode 31 may be located on a side of the light-emitting functional layer 32 facing away from the substrate 10, the second electrode 33 is located on a side of the light-emitting functional layer 32 facing the substrate 10, and the first electrode 31 is connected to the third isolation portion 22, such that the first electrodes 31 of the plurality of light-emitting units 30 can be electrically connected through the isolation structure 20 to form a continuous electrode to ensure normal light emission of the light-emitting units 30. One of the first electrode 31 and the second electrode 33 may serve as an anode of the light-emitting unit 30 and the other as a cathode of the light-emitting unit 30, and the embodiments of the present application are exemplified by taking the first electrode 31 as the cathode of the light-emitting unit 30 and the second electrode 33 as the anode of the light-emitting unit 30. It should be noted that the light-emitting functional layer 32 may be formed by stacking a plurality of film layer structures. In one embodiment, the light-emitting functional layer 32 may include a hole injection layer (HIL), a hole transport layer (HTL), a light-emitting layer, an electron injection layer (EIL), and an electron transport layer (ETL) that are stacked. Reference can be made to related content of the isolation structure 20 that is recorded in patent applications Nos. PCT/CN2023/134518, 202310759370.2, 202310740412.8, 202310771124.9, 202311499823.9, and 202311616249.0.

In these embodiments, the orthographic projection of the protrusions 232 or recesses 235 on the substrate 10 is configured to be within the orthographic projection of the third isolation portion 22 on the substrate 10, to avoid the protrusions 232 from blocking the sidewall of the third isolation portion 22 facing the isolation opening 21, so that a material of the first electrode 31 falling into the isolation opening 21 can lap the third isolation portion 22, such that the first electrodes 31 of the plurality of light-emitting units 30 can be connected through the isolation structure 20 to form a continuous electrode, thereby ensuring the light emission performance of the display panel 100, and improving a performance of the display panel 100.

In one embodiment, the first electrode 31 is in contact with part of corresponding protrusions 232 or recesses 235, to ensure the first electrode 31 to lap the third isolation portion 22, and increasing a bonding strength between the first electrode 31 and the isolation structure 20, thereby lowering a risk of peeling of the first electrode 31 relative to the isolation structure 20.

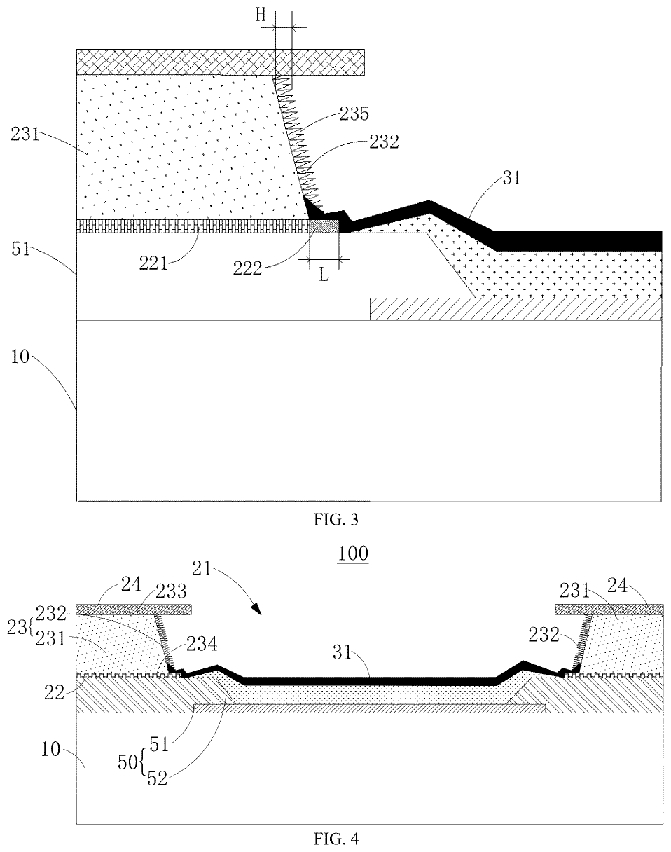

Referring to FIG. 3, in some embodiments, the third isolation portion 22 includes a second sub-portion 221, and an extension sub-portion 222 disposed on a side of the second sub-portion 221 facing the isolation opening 21. The second sub-portion 221 is in contact with a surface of a side of the first sub-portion 231 facing the substrate 10, the extension sub-portion 222 protrudes, relative to the surface of the side of the first sub-portion 231 facing the substrate 10, toward the isolation opening 21 in a direction parallel to the substrate 10, and in the direction parallel to the substrate 10, a ratio Z of an extension length of the extension sub-portion 222 to a height of the protrusions 232 satisfies: 1.5≤Z≤3.

In one embodiment, the extension length of the extension sub-portion 222 in the direction parallel to the substrate 10 refers to a distance from a side of the extension sub-portion 222 close to the isolation opening 21 to a side of the second sub-portion 221 close to the isolation opening 21, and the height of the protrusions 232 in the direction parallel to the substrate 10 refers to a distance from the end of the protrusion 232 close to the isolation opening 21 to the first sub-portion 231. The second sub-portion 221 is in contact with the surface of the side of the first sub-portion 231 facing the substrate 10, and the orthographic projection of the second sub-portion on the substrate 10 overlaps with an orthographic projection of the first sub-portion 231 on the substrate 10. The extension sub-portion 222 is disposed on a side of the second sub-portion 221 facing the isolation opening 21, and protrudes, relative to the surface of the side of the first sub-portion 231 facing the substrate 10, toward the isolation opening 21 in a direction parallel to the substrate 10. That is, an orthographic projection of the extension sub-portion 222 on the substrate 10 and an orthographic projection of the first sub-portion 231 on the substrate 10 are staggered, with the extension sub-portion not in contact with the first sub-portion 231. It should be noted that the ratio of the extension length of the extension sub-portion 222 to the height of the protrusions 232 is greater than or equal to 1.5 and less than 3, in one embodiment, the ratio may be 1.5, 2, 2.3, 2.7, 2.9, 3, or the like.

In these embodiments, by appropriately configuring the ratio of the extension length of the extension sub-portion 222 in the direction parallel to the substrate 10 to the height of the protrusions 232 in the direction parallel to the substrate 10, it is possible to increase a lap area between the first electrode 31 and the third isolation portion 22, improving a lap yield between the two, and reducing a lap impedance between the first electrode 31 and the third isolation portion 22.

In one embodiment, the extension length L1 of the extension sub-portion 222 satisfies: 0.1 μm≤L1≤0.15 μm, so that the extension length of the extension sub-portion 222 in the direction parallel to the substrate 10 is appropriately set.

It should be noted that the extension sub-portion 222 has the extension length greater than or equal to 0.1 μm and less than or equal to 0.15 μm, which may be 0.1 μm. 0.11 μm, 0.12 μm, 0.13 μm, 0.14 μm, 0.15 μm, or the like.

In one embodiment, the height H1 of the protrusions 232 satisfies: 0.05 μm≤H1≤0.07 μm, so that the height of the protrusions 232 is appropriately set.

It should be noted that the height of the protrusions 232 is greater than or equal to 0.05 μm and less than or equal to 0.07 μm, which may be 0.05 μm, 0.005 μm, 0.006 μm, 0.065 μm, 0.068 μm, 0.07 μm, or the like.

In one embodiment, the orthographic projection of the third isolation portion 22 on the substrate 10 is within the orthographic projection of the second isolation portion 24 on the substrate 10, which reduces a risk of lapping between the light-emitting functional layer 32 and the third isolation portion 22, to lower a risk of current leakage in the light-emitting units 30.

Still referring to FIG. 1, in some embodiments, the encapsulation portion 40 extends to the side of the isolation structure 20 facing away from the substrate 10.

In one embodiment, the encapsulation portion 40 may extend from a side of the light-emitting units 30 facing away from the substrate 10, via the sidewall of the isolation structure 20 facing the isolation opening 21, to the side of the isolation structure 20 facing away from the substrate 10, to prolong an intrusion path of moisture and oxygen, thereby improving the encapsulation performance, and to increase a contact area between the encapsulation portion 40 and the isolation structure 20, thereby lowering a risk of peeling of the encapsulation portion 40 from the isolation structure 20.

In one embodiment, the material of the first encapsulation layer includes an inorganic material. The inorganic material can provide excellent mechanical support and encapsulation protection, to prevent the display panel 100 from being affected by environmental factors, and can effectively block external harmful substances including moisture and oxygen from entering an interior of the display panel 100, thereby improving both service life and stability of the display panel 100.

In one embodiment, the protrusions 232 are burr-like, so as to further increase the contact area between the isolation structure 20 and the encapsulation portion 40, improving the bonding capability between the two, and further lowering the risk of peeling of the encapsulation portion 40 from the isolation structure 20.

In one embodiment, an orthographic projection of the protrusions 232 on the first sub-portion 231 in the direction parallel to the substrate 10 is bar-shaped, so as to increase a surface area of the protrusions 232, and further increasing the contact area between the isolation structure 20 and the encapsulation portion 40.

In one embodiment, the orthographic projection of the protrusions 232 on the first sub-portion 231 in the direction parallel to the substrate 10 is bar-shaped, and the protrusions 232 extend in the direction parallel to the substrate 10.

It can be understood that when peeling of the encapsulation portion 40 from the isolation structure 20 occurs, the encapsulation portion 40 first separates from a surface of a side of the protrusion 232 away from the substrate 10 in a thickness direction of the substrate 10, and subsequently separates from other surfaces of the protrusion 232. Therefore, in this embodiment, by configuring the protrusion 232 to extend in the direction parallel to the substrate 10, it is possible to increase areas of two surfaces of the protrusion 232 in the thickness direction of the substrate 10, improving a bonding capability between the surface of the side of the protrusion 232 away from the substrate 10 in the thickness direction of the substrate 10 and the encapsulation portion 40, thereby lowering a risk of separation of the encapsulation portion 40 from the protrusion 232.

In one embodiment, the orthographic projection of the protrusions 232 on the first sub-portion 231 in the direction parallel to the substrate 10 is bar-shaped, and the protrusions 232 extend in a curved trajectory, so as to further increase the surface area of the protrusions 232.

In some embodiments, the display panel 100 further includes a second encapsulation layer disposed on a side of the first encapsulation layer facing away from the array substrate 10. The second encapsulation layer can further isolate external moisture, oxygen, and other substances from entering the interior of the display panel 100.

In one embodiment, the second encapsulation layer includes an organic material. The second encapsulation layer may be made of an organic material such as a polymer. The second encapsulation layer has a thickness greater than that of the first encapsulation layer and exhibits higher flexibility, thereby better adapting to the bending and curvature of the display panel 100. In addition, the organic material can also serve to buffer an external force.

In some optional embodiments, the display panel 100 may further include a third encapsulation layer located on a side of the second encapsulation layer facing away from the substrate 10. The third encapsulation layer covers the second encapsulation layer, so as to further improve the encapsulation performance. The third encapsulation layer includes an inorganic material, thereby providing excellent mechanical support and encapsulation protection to prevent the display panel 100 from being affected by external environmental factors, and further blocking external harmful substances such as moisture and oxygen from entering the interior of the display panel 100.

In some embodiments, materials of both the third isolation portion 22 and the first sub-portion 231 include conductive materials, such that the first electrodes 31 of the plurality of light-emitting units 30 can be connected through the third isolation portion 22 to form a continuous electrode.

In one embodiment, an oxidation rate of the first sub-portion 231 is greater than an oxidation rate of the third isolation portion 22, and therefore, the sidewall of the first sub-portion 231 facing the isolation opening 21 can be oxidized to form a rough surface, thereby being advantageous for improving the bonding capability between the encapsulation portion 40 and the isolation structure 20.

It should be noted that, in this embodiment, the protrusions 232 may be formed by oxidation of a sidewall of the first isolation portion 23 facing the isolation opening 21, where an oxidized part of the first isolation portion 23 forms the protrusions 232, and a non-oxidized part of the first isolation portion 23 remains as the first sub-portion 231. Under this configuration, the protrusions 232 can be formed on the sidewall of the first sub-portion 231 facing the isolation opening 21 without the need for additional processes, thereby simplifying process steps. Alternatively, the protrusions 232 may also be formed on the sidewall of the first sub-portion 231 facing the isolation opening 21 through a specific process, which is not limited in this embodiment.

In one embodiment, a material of the third isolation portion 22 includes an oxidation-resistant conductive material, thereby preventing oxidation of the material of the third isolation portion 22 from affecting the lapping performance with the first electrode 31.

In one embodiment, the material of the third isolation portion 22 includes at least one of molybdenum, titanium, or copper, such that the third isolation portion 22 possesses both excellent conductivity and oxidation resistance.

In one embodiment, a material of the first sub-portion 231 includes aluminum, such that the first sub-portion 231 exhibits both good electrical conductivity and a high oxidation rate.

In some embodiments, a material of the protrusions 232 includes an oxide, and the protrusions 232 may be formed by oxidation of the corresponding material, thereby lowering a difficulty in forming the protrusions 232 with a specific morphology.

In one embodiment, the material of the protrusions 232 and the material of the first sub-portion 231 include a same element, thereby increasing a bonding strength between the protrusions 232 and the first sub-portion 231, and lowering a risk of separation of the protrusions 232 from the first sub-portion 231. Moreover, since the material of the protrusions 232 includes the oxide, and the material of the protrusions 232 and the material of the first sub-portion 231 include a same element, the protrusions 232 can be formed by oxidation of the material of the sidewall of the first isolation portion 23 facing the isolation opening 21, with the non-oxidized part of the first isolation portion 23 forming the first sub-portion 231, such that the protrusions 232 are located on the sidewall of the first sub-portion 231 facing the isolation opening 21. In this process, the protrusions 232 can be prepared on the sidewall of the first sub-portion 231 facing the isolation opening 21 without the need for additional processes, thereby simplifying process steps.

In one embodiment, the material of the first sub-portion 231 includes a metal, and the material of the protrusions 232 includes an oxide of the metal, that is, the protrusions 232 can be formed by oxidation of the material of the first sub-portion 231, and therefore, no additional process needs to be provided to prepare the protrusions, thereby simplifying process steps and lowering a process difficulty. Moreover, the protrusions 232 are formed by a growth of the material of the first sub-portion 231, which can further increase the bonding strength between the protrusions 232 and the first sub-portion 231.

In one embodiment, the material of the first sub-portion 231 includes aluminum, and the material of the protrusions 232 includes aluminum oxide, which is advantageous for reducing a resistivity of the first isolation portion 23, such that the first isolation portion 23 has good electrical conductivity, which facilitates oxidation formation of the protrusions 232 on the sidewall of the first isolation portion 23 facing the isolation opening 21.

It should be noted that, on the sidewall of the first sub-portion 231 facing the isolation opening 21, a plurality of protrusions 232 may be distributed at intervals or sequentially and continuously in a thickness direction of the substrate 10 or a circumferential direction of the isolation opening 21, a plurality of protrusions 232 may be distributed at intervals or sequentially and continuously in a thickness direction of the substrate 10 and a circumferential direction of the isolation opening 21, and shapes and sizes of the plurality of protrusions 232 may be same or different, which is not limited in this embodiment.

Referring to FIG. 4, in some embodiments, the first isolation portion 23 includes a first surface 233 facing the substrate 10 and a second surface 234 facing away from the substrate 10. An orthographic projection of the second surface 234 on the substrate 10 is within an orthographic projection of the first surface 233 on the substrate 10, thereby facilitating the first electrode 31 to climb over the third isolation portion 22 to reach the sidewall of the first isolation portion 23 facing the isolation opening 21, so as to increase a contact area between the first electrode 31 and the isolation structure 20 and improve a connection strength the two.

It should be noted that the first surface 233 includes a surface of the first sub-portion 231 facing the substrate 10 and a surface of the protrusion 232 facing the substrate 10. The second surface 234 includes a surface of the first sub-portion 231 facing away from the substrate 10 and a surface of the protrusion 232 facing away from the substrate 10.

In one embodiment, in a direction perpendicular to the substrate 10, a cross-sectional shape of the first sub-portion 231 of the first isolation portion 23 is a regular trapezoid, so as to facilitate the first electrode 31 to climb over the third isolation portion 22 to reach the sidewall of the first isolation portion 23 facing the isolation opening 21.

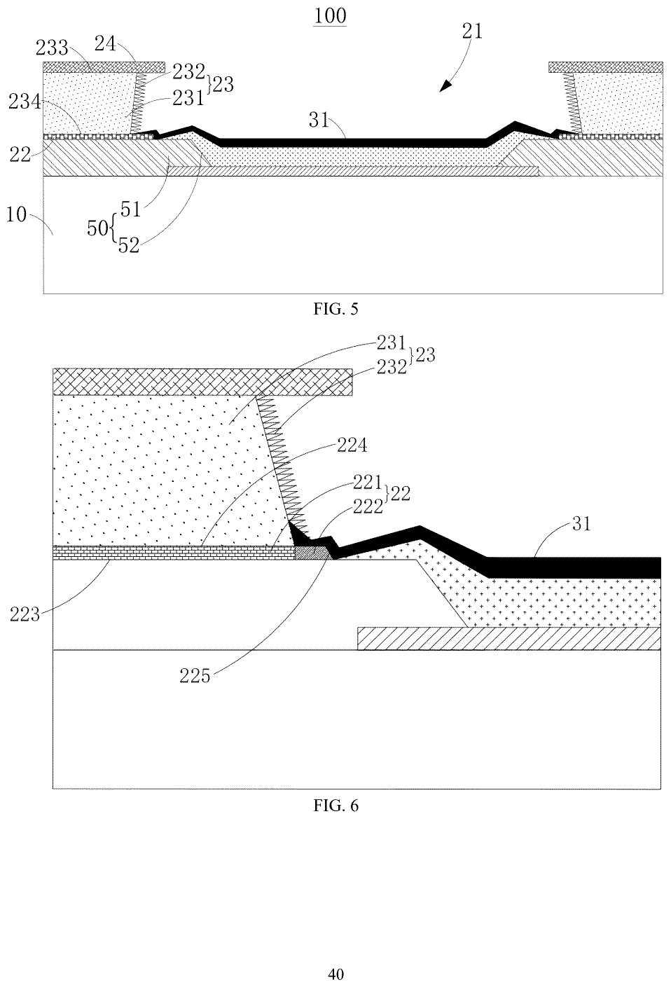

Referring to FIG. 5, in some embodiments, the first isolation portion 23 includes the first surface 233 facing the substrate 10 and the second surface 234 facing away from the substrate 10. An orthographic projection of the first surface 233 on the substrate 10 is within an orthographic projection of the second surface 234 on the substrate 10, so that the first isolation portion 23 can separate the light-emitting material to form the light-emitting units 30 without the need for a fine metal mask, which reduces development and use of the fine metal mask and lowers preparation costs.

In one embodiment, in the direction perpendicular to the substrate 10, the cross-sectional shape of the first sub-portion 231 of the first isolation portion 23 is an inverted trapezoid, such that the first isolation portion 23 has an excellent separating effect on the light-emitting material.

Referring to FIG. 6, in some embodiments, the third isolation portion 22 includes a third surface 223 facing the substrate 10, a fourth surface 224 facing away from the substrate 10, and a side surface 225 connecting the third surface 223 and the fourth surface 224. The first electrode 31 extends to the fourth surface 224 via the side surface 225, so as to increase a contact area between the first electrode 31 and the third isolation portion 22, improving a connection strength between the two, and reducing a connection impedance between the two.

It should be noted that the third surface 223 includes a surface of the second sub-portion 221 facing the substrate 10 and a surface of the extension sub-portion 222 facing the substrate 10, the fourth surface 224 includes a surface of the second sub-portion 221 facing away from the substrate 10 and a surface of the extension sub-portion 222 facing away from the substrate 10, and the side surface 225 is located on a side of the extension sub-portion 222 facing the isolation opening 21.

In one embodiment, the first electrode 31 extends from the fourth surface 224 to the sidewall of the first isolation portion 23 facing the isolation opening 21, and covers at least part of the protrusions 232 or recesses 235, so as to further increase the contact area between the first electrode 31 and the isolation structure 20, and improving the connection strength between the two.

Referring to FIGS. 1 to 5, in some embodiments, the display panel 100 further includes a pixel define layer 50, and the pixel define layer 50 includes a pixel defining portion 51 and a pixel opening 52 enclosed by the pixel defining portion 51. The pixel opening 52 is in communication with the isolation opening 21, part of the light-emitting unit 30 is located in the pixel opening 52, and the isolation structure 20 is disposed on a side of the pixel defining portions 51 facing away from the substrate 10.

The pixel defining portion 51 encloses the pixel opening 52, and part of the light-emitting unit 30 is located in the pixel opening 52, so as to realize light-emitting display of the display panel 100. The pixel opening 52 is communicatively connected with the isolation opening 21, so as to minimize obstruction of the isolation structure 20 to the pixel opening 52 and ensuring the light emission effect of the light-emitting unit 30. The isolation structure 20 is disposed on the side of the pixel defining portion 51 facing away from the substrate 10, and therefore, the first electrode 31 of the light-emitting unit 30 can extend from the pixel opening 52 to the side of the pixel defining portion 51 facing away from the substrate 10, so as to be connected to the third isolation portion 22.

In these embodiments, the isolation structure 20 is disposed on the side of the pixel defining portion 51 facing away from the substrate 10, and the pixel opening 52 is communicatively connected with the isolation opening 21. Therefore, the disposal of the pixel defining portion 51 is equivalent to enabling the isolation opening 21 to have a large height drop. Since the height drop at the isolation opening 21 is large when the light-emitting units 30 is prepared, the light-emitting material is easier to break off at the isolation structure 20, thereby reducing the preparation difficulty of the light-emitting units 30.

It should be noted that the second electrode 33 of the light-emitting unit 30 may be disposed between the pixel defining portion 51 and the substrate 10, and achieves insulation from the isolation structure 20 through the pixel defining portion 51.

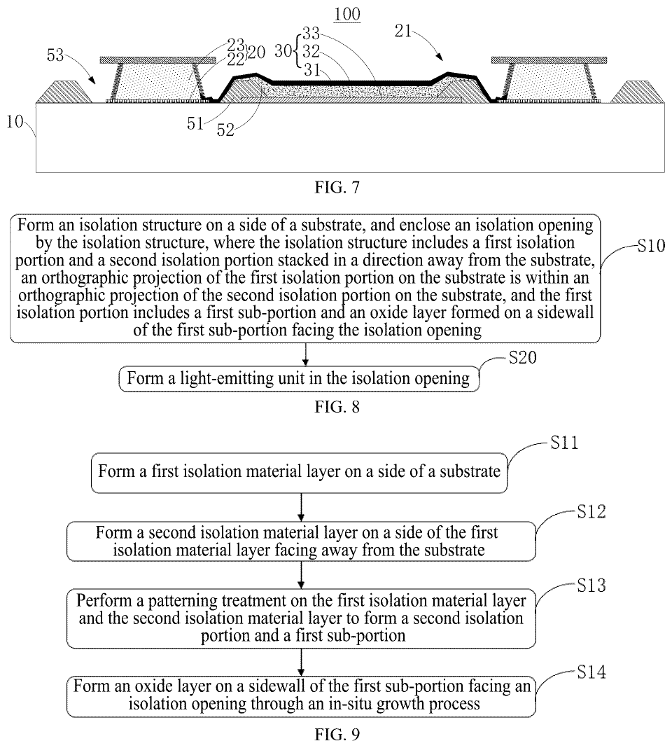

Referring to FIG. 7, in some embodiments, the display panel 100 further includes a pixel define layer. The pixel define layer includes a pixel defining portion 51, a pixel opening 52 and a relief opening 53 that are enclosed by the pixel defining portion 51. The isolation structure 20 is disposed in the relief opening. The first electrode 31 extends from the pixel opening 52 toward the relief opening, and laps the third isolation portion 22 of the isolation structure 20.

The relief opening and the pixel opening 52 are both enclosed by the pixel defining portion 51. An orthographic projection of the relief opening on the substrate 10 and an orthographic projection of the pixel opening 52 on the substrate 10 are staggered. One relief opening may be disposed between two adjacent pixel openings 52, and the pixel opening 52 and the relief opening may be separated by the pixel defining portion 51. The isolation structure 20 is disposed in the relief opening. The first electrode 31 may extend from the pixel opening 52 to the relief opening via a surface of a side of the pixel defining portion 51 facing away from the substrate 10 and is connected to the third isolation portion 22 of the isolation structure 20.

In these embodiments, the isolation structure 20 is disposed in the relief opening. During preparation, the isolation structure 20 may be prepared prior to the second electrode 33 of the light-emitting unit 30. That is, after the isolation structure 20 is completely prepared on the substrate 10, the second electrode 33 is then prepared on the substrate 10, thereby reducing the influence of the preparation of the isolation structure 20 on the second electrode 33, and ensuring that the second electrode 33 is not damaged during the preparation of the isolation structure 20.

In one embodiment, the present application provides a display panel 100. The display panel includes: a substrate 10; an isolation structure 20 disposed on a side of the substrate 10 and enclosing an isolation opening 21, where the isolation structure 20 includes a first isolation portion 23 and a second isolation portion 24 stacked in a direction away from the substrate 10, an orthographic projection of the first isolation portion 23 on the substrate 10 is within an orthographic projection of the second isolation portion 24 on the substrate 10, and the first isolation portion 23 includes a first sub-portion 231 and an oxide layer disposed on a sidewall of the first sub-portion 231 facing the isolation opening 21; and at least part of a light-emitting unit 30 is disposed in the isolation opening 21. Further, the display panel 100 further includes a first encapsulation layer. The first encapsulation layer includes an encapsulation portion 40, and the encapsulation portion 40 is disposed on a side of the light-emitting unit 30 facing away from the substrate 10; and the encapsulation portion 40 covers at least part of the oxide layer.

In these embodiments, the display panel 100 includes the substrate 10, the isolation structure 20, the light-emitting unit 30, and the first encapsulation layer. The isolation structure 20 is disposed on the side of the substrate 10 and encloses the isolation opening 21. The isolation structure 20 includes the first isolation portion 23 and the second isolation portion 24 stacked in the direction away from the substrate 10. The orthographic projection of the first isolation portion 23 on the substrate 10 is within the orthographic projection of the second isolation portion 24 on the substrate 10. Therefore, the isolation structure 20 can separate a light-emitting material to form light-emitting units 30 in such a manner that each light-emitting unit 30 is located in each corresponding isolation opening 21, without the need for a mask, thereby lowering costs. The first isolation portion 23 includes the first sub-portion 231 and the oxide layer disposed on the sidewall of the first sub-portion 231 facing the isolation opening 21. The first encapsulation layer includes the encapsulation portion 40 disposed on a side of the light-emitting unit 30 facing away from the substrate 10. The encapsulation portion 40 can act as an independent encapsulation for each light-emitting unit 30, so as to lower a risk of the light-emitting unit 30 being affected by factors including moisture, and improving reliability of the display panel 100. The encapsulation portion 40 covers at least part of the oxide layer, so as to increase a contact area between the encapsulation portion 40 and the isolation structure 20, thereby lowering a risk of peeling of the encapsulation portion 40 from the isolation structure 20, and improving an encapsulation performance of the encapsulation portion 40 on the light-emitting unit 30.

It should be noted that there may be a plurality of encapsulation portions 40, and the plurality of encapsulation portions 40 may encapsulate the plurality of light-emitting units 30 in a one-to-one correspondence, thereby improving encapsulation reliability for the light-emitting units 30.

In some embodiments, the encapsulation portion 40 extends to a side of the isolation structure 20 facing away from the substrate 10, so as to prolong an intrusion path of moisture and oxygen, thereby improving the encapsulation performance, and to increase the contact area between the encapsulation portion 40 and the isolation structure 20, thereby lowering a risk of peeling of the encapsulation portion 40 from the isolation structure 20.

In one embodiment, a surface roughness of the oxide layer is greater than a surface roughness of a side of the first sub-portion 231 facing away from the substrate 10, so as to enhance a bonding capability between the encapsulation portion 40 and the isolation structure 20, and lowering a risk of peeling of the encapsulation portion 40 from the isolation structure 20 during the subsequent process or usage.

Still referring to FIG. 1, in one embodiment, the oxide layer includes a plurality of protrusions 232. The plurality of protrusions 232 are disposed on a side of the first sub-portion 231 facing the isolation opening 21, and the encapsulation portion 40 can cover the plurality of protrusions 232, so as to further improve the bonding capability between the encapsulation portion 40 and the isolation structure 20.

In one embodiment, the protrusions 232 are burr-like, so as to further increase the contact area between the isolation structure 20 and the encapsulation portion 40, improving the bonding capability between the two, and further lowering the risk of peeling of the encapsulation portion 40 from the isolation structure 20.

In one embodiment, the material of the first encapsulation layer includes an inorganic material. The inorganic material can provide excellent mechanical support and encapsulation protection, so as to prevent the display panel 100 from being affected by environmental factors, and can effectively block external harmful substances including moisture and oxygen from entering an interior of the display panel 100, thereby improving both service life and stability of the display panel 100.

In some embodiments, the isolation structure 20 further includes a third isolation portion 22 disposed on a side of the first isolation portion 23 close to the substrate 10; an orthographic projection of the oxide layer on the substrate 10 is within an orthographic projection of the third isolation portion 22 on the substrate 10; and each light-emitting unit 30 includes a first electrode 31 lapping the third isolation portion 22.

The third isolation portion 22 is disposed on the side of the first isolation portion 23 close to the substrate 10, and the disposal of the third isolation portion 22 is equivalent to enabling the isolation opening 21 to have a large height drop, so as to facilitate separating the light-emitting material to form the light-emitting units 30. Each light-emitting unit 30 may include the first electrode 31, a light-emitting functional layer 32, and a second electrode 33 that are stacked. The first electrode 31 may be located on a side of the light-emitting functional layer 32 facing away from the substrate 10, the second electrode 33 is located on a side of the light-emitting functional layer 32 facing the substrate 10, and the first electrode 31 is connected to the third isolation portion 22, such that the first electrodes 31 of the plurality of light-emitting units 30 can be electrically connected through the isolation structure 20 to form a continuous electrode to ensure normal light emission of the light-emitting units 30. One of the first electrode 31 and the second electrode 33 may serve as an anode of the light-emitting unit 30 and the other as a cathode of the light-emitting unit 30, and the embodiments of the present application are exemplified by taking the first electrode 31 as the cathode of the light-emitting unit 30 and the second electrode 33 as the anode of the light-emitting unit 30. It should be noted that the light-emitting functional layer 32 may be formed by stacking a plurality of film layer structures. In one embodiment, the light-emitting functional layer 32 may include a hole injection layer (HIL), a hole transport layer (HTL), a light-emitting layer, an electron injection layer (EIL), and an electron transport layer (ETL) that are stacked.

In these embodiments, the orthographic projection of the oxide layer on the substrate 10 is configured to be within the orthographic projection of the third isolation portion 22 on the substrate 10, to avoid the oxide layer from blocking the sidewall of the third isolation portion 22 facing the isolation opening 21, so that a material of the first electrode 31 falling into the isolation opening 21 can lap the third isolation portion 22, such that the first electrodes 31 of the plurality of light-emitting units 30 can be connected through the isolation structure 20 to form a continuous electrode, thereby ensuring the light emission performance of the display panel 100, and improving a performance of the display panel 100.

In one embodiment, each first electrode 31 is in contact with part of each corresponding oxide layer, to ensure the first electrode 31 to lap the third isolation portion 22, and increasing a bonding strength between the first electrode 31 and the isolation structure 20, thereby lowering a risk of peeling of the first electrode 31 from the isolation structure 20.

Still referring to FIG. 3, in some embodiments, the third isolation portion 22 includes a second sub-portion 221, and an extension sub-portion 222 disposed on a side of the second sub-portion 221 facing the isolation opening 21. The second sub-portion 221 is in contact with a surface of a side of the first sub-portion 231 facing the substrate 10, the extension sub-portion 222 protrudes, relative to the surface of the side of the first sub-portion 231 facing the substrate 10, toward the isolation opening in a direction parallel to the substrate 10, and in the direction parallel to the substrate 10, a ratio Z of an extension length of the extension sub-portion 222 to a thickness of the oxide layer satisfies: 1.5≤Z≤3, so that by appropriately configuring the ratio of the extension length of the extension sub-portion 222 in the direction parallel to the substrate 10 to the thickness of the oxide layer in the direction parallel to the substrate 10, it is possible to increase a lap area between the first electrode 31 and the third isolation portion 22, improving a lap yield between the two, and reducing a lap impedance between the first electrode 31 and the third isolation portion 22.

It should be noted that the ratio of the extension length of the extension sub-portion 222 to the thickness of the oxide layer is greater than or equal to 1.5 and less than 3, in one embodiment, the ratio may be 1.5, 2, 2.3, 2.7, 2.9, 3, or the like.

In one embodiment, the extension length L1 of the extension sub-portion 222 satisfies: 0.05 μm<L1≤0.15 μm, so that a width of the extension sub-portion 222 in the direction parallel to the substrate 10 is appropriately configured.

It should be noted that the extension sub-portion 222 has the extension length greater than or equal to 0.05 μm and less than or equal to 0.15 μm, which may be 0.06 μm, 0.08 μm, 0.1 μm, 0.12 μm, 0.14 μm, 0.15 μm, or the like.

In one embodiment, the extension length L1 of the extension sub-portion 222 satisfies: 0.1 μm≤L1≤0.15 μm, so that the width of the extension sub-portion 222 in the direction parallel to the substrate 10 is appropriately configured.

It should be noted that the extension sub-portion 222 has the extension length greater than or equal to 0.1 μm and less than or equal to 0.15 μm, which may be 0.1 μm, 0.11 μm, 0.12 μm, 0.13 μm, 0.14 μm, 0.15 μm, or the like.

In one embodiment, the thickness H2 of the oxide layer satisfies: 0.05 μm≤H2≤0.07 μm, so that the thickness of the oxide layer is appropriately configured.

It should be noted that the thickness of the oxide layer is greater than or equal to 0.05 μm and less than or equal to 0.07 μm, which may be 0.05 μm, 0.005 μm, 0.006 μm, 0.065 μm, 0.068 μm, 0.07 μm, or the like.

In some embodiments, the light-emitting unit 30 further includes a second electrode 33 and a light-emitting functional layer 32, where the second electrode 33, the light-emitting functional layer 32, and the first electrode 31 are stacked in the direction away from the substrate 10 to achieve light emission.

In one embodiment, the light-emitting functional layer 32 covers part of the extension sub-portion 222.

The light-emitting functional layer 32 may extend from a sidewall of the extension sub-portion 222 facing the isolation opening 21 to a side of the extension sub-portion 222 facing away from the substrate 10, and cover part of the extension sub-portion 222, so as to improve a strength of the light-emitting functional layer 32.

In one embodiment, the extension sub-portion 222 includes a first part, and a second part, where the first part is covered by the light-emitting functional layer 32, the second part is exposed relative to the light-emitting functional layer 32, and a length L2 of the second part in the direction parallel to the substrate 10 satisfies: 0.02 μm<L2<0.15 μm. In one embodiment, the length of the second part may be 0.03 μm, 0.05 μm, 0.07 μm, 0.09 μm, 0.1 μm, 0.12 μm, 0.15 μm, or the like, such that the extension sub-portion 222 has a sufficient region for connection with the first electrode 31, thereby reducing a lap impedance between the first electrode 31 and the extension sub-portion 222.

Referring to FIG. 8, in one embodiment, the present application provides a preparation method for a display panel 100. The method includes the following steps.

S10: Form an isolation structure 20 on a side of a substrate 10, and enclose an isolation opening 21 by the isolation structure 20, where the isolation structure 20 includes a first isolation portion 23 and a second isolation portion 24 stacked in a direction away from the substrate 10, an orthographic projection of the first isolation portion 23 on the substrate 10 is within an orthographic projection of the second isolation portion 24 on the substrate 10, and the first isolation portion 23 includes a first sub-portion 231 and an oxide layer formed on a sidewall of the first sub-portion 231 facing the isolation opening 21.

S20: Form a light-emitting unit 30 in the isolation opening 21.

Further, the method further includes forming a first encapsulation layer, where the first encapsulation layer includes an encapsulation portion 40, and the encapsulation portion 40 is disposed on a side of the light-emitting unit 30 facing away from the substrate 10; and the encapsulation portion 40 covers at least part of the oxide layer.

In these embodiments, the isolation structure 20 is first formed on the side of the substrate 10, and the isolation opening 21 is enclosed by the isolation structure 20. The isolation structure 20 includes the first isolation portion 23 and the second isolation portion 24 stacked in the direction away from the substrate 10. The orthographic projection of the first isolation portion 23 on the substrate 10 is within the orthographic projection of the second isolation portion 24 on the substrate 10. The first isolation portion 23 includes the first sub-portion 231 and the oxide layer formed on the sidewall of the first sub-portion 231 facing the isolation opening 21. Subsequently, the light-emitting unit 30 and the first encapsulation layer are formed in the isolation opening 21. The first encapsulation layer includes the encapsulation portion 40, the encapsulation portion 40 is disposed on the side of the light-emitting unit 30 facing away from the substrate 10. The encapsulation portion 40 covers at least part of the oxide layer, and the light-emitting unit 30 is independently encapsulated by the encapsulation portion 40, while a contact area between the encapsulation portion 40 and the isolation structure 20 is increased, a risk of peeling of the encapsulation portion 40 from the isolation structure 20 is lowered, and an encapsulation effect of the encapsulation portion 40 on the light-emitting unit 30 is improved.

Referring to FIG. 9, in some embodiments, the step of forming the isolation structure 20 on the side of the substrate 10 includes the following steps.

S11: Form a first isolation material layer on a side of a substrate 10.

S12: Form a second isolation material layer on a side of the first isolation material layer facing away from the substrate 10. The first isolation material layer and the second isolation material layer may both be conductive materials, with the second isolation material layer is located on a side of the first isolation material layer facing away from the substrate 10 and covering the first isolation material layer.

S13: Perform a patterning treatment on the first isolation material layer and the second isolation material layer to form a second isolation portion 24 and a first sub-portion 231. In one embodiment, forward etching may be first performed on the first isolation material layer and the second isolation material layer, followed by lateral etching performed on the second isolation material layer, to form the second isolation portion 24 and the first sub-portion 231.

S14: Form an oxide layer on a sidewall of the first sub-portion 231 facing an isolation opening 21 through an in-situ growth process. In the in-situ growth process, a material of the sidewall of the first sub-portion 231 facing the isolation opening 21 may undergo an oxidation reaction with oxygen in air or the external environment, to form the oxide layer.

In these embodiments, the first isolation material layer is first formed on the side of the substrate 10, and the second isolation material layer is formed on the side of the first isolation material layer facing away from the substrate 10. Subsequently, the first isolation material layer and the second isolation material layer undergo the patterning treatment to form the second isolation portion 24 and the first sub-portion 231. Finally, the oxide layer is formed on the sidewall of the first sub-portion 231 facing the isolation opening 21 through the in-situ growth process, and during subsequent preparation of the encapsulation portion 40, the encapsulation portion 40 can cover at least part of the oxide layer, to enhance a bonding capability between the encapsulation portion 40 and the isolation structure 20 and to lower the risk of peeling of the encapsulation portion 40 from the isolation structure 20 during the subsequent process or usage.

In one embodiment, the present application provides a display apparatus. The display apparatus includes the display panel 100 according to any one of the preceding embodiments, or the display panel 100 prepared by the preparation method according to any one of the preceding embodiments. The display apparatus employs all the embodiments of all the above embodiments, and therefore has at least all the beneficial effects brought by the embodiments of the above embodiments, which will not be described in detail herein.

The display apparatus may be any apparatus with a display function, in one embodiment, a mobile device, such as a mobile phone, a tablet computer, a laptop computer, a palmtop computer, a vehicle-mounted electronic device, a wearable device, an ultra-mobile personal computer (UMPC), a netbook, or a personal digital assistant (PDA), or a non-mobile device, such as a personal computer (PC), a television (TV), a teller machine, or a self-service machine.

Although the embodiments disclosed in the present application are as described above, the content described is only embodiments used to facilitate the understanding of the present application rather than to limit the present disclosure. Any person may make any modification and variation in the form and details of embodiment without departing from the present application, but the protection of the present application shall still be subject to the appended claims.

The above descriptions are merely specific embodiments of the present application. It is understood that, for convenience and brevity of description, for replacement of other connection manners described above, reference may be made to the corresponding processes in the above method embodiments, and details are not repeated herein. It should be understood that the protection of the present application is not limited thereto, any equivalent modification or replacement that can be easily conceived within the disclosed in the present application by any person shall fall within the protection of the present application.

What is claimed is:

1. A display panel, comprising:
a substrate;
an isolation structure disposed on a side of the substrate and enclosing an isolation opening, wherein the isolation structure comprises a first isolation portion and a second isolation portion stacked in a direction away from the substrate, an orthographic projection of the first isolation portion on the substrate is within an orthographic projection of the second isolation portion on the substrate, and the first isolation portion comprises a first sub-portion and a plurality of protrusions or recesses disposed on a sidewall of the first sub-portion facing the isolation opening;
a light-emitting unit, wherein at least part of the light-emitting unit is disposed in the isolation opening; and
a first encapsulation layer comprising an encapsulation portion, wherein the encapsulation portion is disposed on a side of the light-emitting unit facing away from the substrate, wherein the encapsulation portion covers at least part of the plurality of protrusions or recesses.

2. The display panel according to claim 1, wherein the isolation structure further comprises a third isolation portion disposed on a side of the first isolation portion close to the substrate, and an orthographic projection of the protrusions or recesses on the substrate is within an orthographic projection of the third isolation portion on the substrate.

3. The display panel according to claim 1, wherein the encapsulation portion extends to a side of the isolation structure facing away from the substrate;
a material of the first encapsulation layer comprises an inorganic material; and
the plurality of protrusions are burr-like; or
an orthographic projection of the protrusions on the first sub-portion in a direction parallel to the substrate is bar-shaped.

4. The display panel according to claim 2, wherein a material of the third isolation portion and a material of the first sub-portion both comprise a conductive material; and
an oxidation rate of the first sub-portion is greater than an oxidation rate of the third isolation portion.

5. The display panel according to claim 4, wherein a material of the protrusions comprises an oxide; and
the material of the protrusions and the material of the first sub-portion comprise a same element.

6. The display panel according to claim 1, wherein the first isolation portion comprises a first surface facing the substrate and a second surface facing away from the substrate, wherein an orthographic projection of the second surface on the substrate is within an orthographic projection of the first surface on the substrate.

7. The display panel according to claim 1, wherein the first isolation portion comprises a first surface facing the substrate and a second surface facing away from the substrate, wherein an orthographic projection of the first surface on the substrate is within an orthographic projection of the second surface on the substrate.

8. The display panel according to claim 2, wherein the third isolation portion comprises a third surface facing the substrate, a fourth surface facing away from the substrate, and a side surface connecting the third surface and the fourth surface, the light-emitting unit comprises a first electrode, wherein the first electrode extends to the fourth surface via the side surface; and
the first electrode extends from the fourth surface to a sidewall of the first isolation portion facing the isolation opening, and covers at least part of the protrusions or recesses.

9. The display panel according to claim 1, wherein the display panel further comprises a pixel define layer, wherein the pixel define layer comprises a pixel defining portion and a pixel opening enclosed by the pixel defining portion, the pixel opening is in communication with the isolation opening, part of the light-emitting unit is located in the pixel opening, and the isolation structure is disposed on a side of the pixel defining portion facing away from the substrate.

10. The display panel according to claim 2, wherein the display panel further comprises a pixel define layer, wherein the pixel define layer comprises a pixel defining portion, and a pixel opening and a relief opening that are enclosed by the pixel defining portion, the isolation structure is disposed in the relief opening, and the first electrode extends from the pixel opening toward the relief opening and laps the third isolation portion of the isolation structure.

11. The display panel according to claim 2, wherein the light-emitting unit comprises a first electrode lapping the third isolation portion; the encapsulation portion covers the first electrode; and the first electrode is in contact with part of the protrusions or recesses.

12. The display panel according to claim 2, wherein the third isolation portion comprises a second sub-portion, and an extension sub-portion disposed on a side of the second sub-portion facing the isolation opening, wherein the second sub-portion is in contact with a surface of a side of the first sub-portion facing the substrate, the extension sub-portion extends, relative to the surface of the side of the first sub-portion facing the substrate, toward the isolation opening in a direction parallel to the substrate, and a ratio Z of an extension length of the extension sub-portion in the direction parallel to the substrate to a height of the protrusions satisfies: 1.5≤Z≤3.

13. The display panel according to claim 5, wherein the material of the first sub-portion comprises a metal, and the material of the protrusions comprises an oxide of the metal.

14. A display panel, comprising:
a substrate;
an isolation structure disposed on a side of the substrate and enclosing an isolation opening, wherein the isolation structure comprises a first isolation portion and a second isolation portion stacked in a direction away from the substrate, an orthographic projection of the first isolation portion on the substrate is within an orthographic projection of the second isolation portion on the substrate, and the first isolation portion comprises a first sub-portion and an oxide layer disposed on a sidewall of the first sub-portion facing the isolation opening; and
a light-emitting unit, wherein at least part of the light-emitting unit is disposed in the isolation opening.

15. The display panel according to claim 14, wherein the display panel further comprises a first encapsulation layer, wherein the first encapsulation layer comprises an encapsulation portion, and the encapsulation portion is disposed on a side of the light-emitting unit facing away from the substrate and covers at least part of the oxide layer, and
the encapsulation portion extends to a side of the isolation structure facing away from the substrate.

16. The display panel according to claim 15, wherein a surface roughness of the oxide layer is greater than a surface roughness of a side of the first sub-portion facing away from the substrate.

17. The display panel according to claim 16, wherein the oxide layer comprises a plurality of protrusions disposed on a side of the first sub-portion facing the isolation opening.

18. The display panel according to claim 14, wherein the isolation structure further comprises a third isolation portion disposed on a side of the first isolation portion close to the substrate; and an orthographic projection of the oxide layer on the substrate is within an orthographic projection of the third isolation portion on the substrate;
the light-emitting unit comprises a first electrode lapping the third isolation portion; and
the first electrode is in contact with at least part of the oxide layer.

19. The display panel according to claim 18, wherein the third isolation portion comprises a second sub-portion, and an extension sub-portion disposed on a side of the second sub-portion facing the isolation opening, wherein the second sub-portion is in contact with a surface of a side of the first sub-portion facing the substrate, the extension sub-portion extends, relative to the surface of the side of the first sub-portion facing the substrate, toward the isolation opening in a direction parallel to the substrate, and a ratio Z of an extension length of the extension sub-portion in the direction parallel to the substrate to a thickness of the oxide layer satisfies: 1.5≤Z≤3;
the light-emitting unit further comprises a second electrode and a light-emitting functional layer, wherein the second electrode, the light-emitting functional layer, and the first electrode are stacked in the direction away from the substrate; and
the light-emitting functional layer covers part of the extension sub-portion, or the light-emitting functional layer is spaced apart from the extension sub-portion.

20. A display apparatus, comprising:
a display panel, comprising:
a substrate;
an isolation structure disposed on a side of the substrate and enclosing an isolation opening, wherein the isolation structure comprises a first isolation portion and a second isolation portion stacked in a direction away from the substrate, an orthographic projection of the first isolation portion on the substrate is within an orthographic projection of the second isolation portion on the substrate, and the first isolation portion comprises a first sub-portion and a plurality of protrusions or recesses disposed on a sidewall of the first sub-portion facing the isolation opening;
a light-emitting unit, wherein at least part of the light-emitting unit is disposed in the isolation opening; and
a first encapsulation layer comprising an encapsulation portion, wherein the encapsulation portion is disposed on a side of the light-emitting unit facing away from the substrate, wherein the encapsulation portion covers at least part of the plurality of protrusions or recesses.
